(19) United States
(12) Patent Application Publication
(10) Pub. No.: US 2014/0175658 A1
(43) Pub. Date: Jun. 26, 2014

(54) ANCHORING A TRACE ON A SUBSTRATE TO REDUCE PEELING OF THE TRACE

(71) Applicant: QUALCOMM INCORPORATED, San Diego, CA (US)

(72) Inventors: Chin-Kwan Kim, San Diego, CA (US); Houssam W. Jomaa, San Diego, CA (US); Milind P. Shah, San Diego, CA (US); Manuel Aldrete, San Diego, CA (US); Omar J. Bchir, San Marcos, CA (US)

(73) Assignee: Qualcomm Incorporated, San Diego, CA (US)

(21) Appl. No.: 13/764,959

(22) Filed: Feb. 12, 2013

Related U.S. Application Data
(60) Provisional application No. 61/740,885, filed on Dec. 21, 2012.

(51) Int. Cl. H01L 21/50; H01L 23/48

(52) U.S. Cl. CPC H01L 21/50; H01L 23/48
USPC 257/773; 438/118

(57) ABSTRACT

Sonic implementations pertain to a semiconductor device that includes a packaging substrate, a trace coupled to the packaging substrate, and a solder resist layer that covers part of the trace. The trace includes a first portion having a first width, and a second portion having a second width that is wider than the first width. In some implementations, the second portion having the second width increases the area of the trace coupled to the packaging substrate to reduce the likelihood of the trace peeling from the packaging substrate. In some implementations, the solder resist layer further includes an opening such that the second portion of the trace is exposed. In some implementations, the trace further includes a third portion located between the first portion and second portion of the trace and wherein the third portion of the trace is exposed through an opening in the solder resist layer.

### CLAIM OF PRIORITY

The present application claims priority to U.S. Provisional Application No. 61/740,885 entitled “Anchoring a Trace on a Substrate to Reduce Peeling of The Trace”, filed Dec. 21, 2012, which is hereby expressly incorporated by reference herein.

### FIELD

Various features relate to anchoring a trace on a substrate to reduce peeling of the trace.

### BACKGROUND

A thermal compression bonding process is a process used to assemble/package a flip chip, die or semiconductor device to a packaging substrate. Such a flip chip is often referred to as a thermal compression flip chip (TCFC). Thermal compression bonding processes provide several advantages over traditional bonding processes. For example, thermal compression bonding processes are generally more accurate than other solder bonding processes. Thus, thermal compression bonding processes are ideal when using fine pitch traces on substrate (e.g., less than 100 microns (μm)). In contrast, other solder bonding processes are limited to a bonding pitch that is greater than 100 microns (μm). Thus, TCFCs are typically higher density chips than chips using other bonding processes. However, during a thermal compression bonding process, the chip and the packaging substrate are subject to a lot of stress (e.g., thermal stress), which can result in failure in the assembly of the chip to the packaging substrate.

FIG. 1 illustrates an example of a chip/die coupled to a substrate using a thermal compression bonding process. As shown in FIG. 1, a chip 102 is coupled to a packaging substrate 100 that includes a solder resist layer 104. There are several electrical connections 106 between the chip 102 and the packaging substrate 100. These electrical connections 106 may be defined as under bump metallization (UBM) structures (e.g., UBM structure 110), solder (e.g., solder 112) and traces (e.g., trace 114). FIG. 1 also shows that one of the traces, namely trace 116 has sheared/peeled off its original position as a result of the thermal compression bonding process, resulting in a poor or non-existing connection between the trace 116 and its corresponding UBM structure (e.g., UBM structure 118) and solder (e.g., solder 120). There is also a non-conductive paste (NCP) 108 between the chip 102 and the substrate 100. The NCP 108 provides a protective layer that covers the electrical connections 106 between the chip 102 and the substrate 100.

FIG. 2 illustrates an example of a close up view of a packaging substrate that may be used in a thermal compression process. The packaging substrate 200 includes a first trace 204, a second trace 206 and a solder resist layer 208. The solder resist layer 208 is shown as solder resist layer 208a-c in the side view of FIG. 2. The first and second traces 204-206 may be copper traces. As shown in FIG. 2, part of the first and second traces 204-206 are covered by the solder resist layer 208. The solder resist covered portions of the first and second traces 204-206 are denoted by the dashed lines shown in the top view of FIG. 2. The solder resist layer 208 includes a first opening 210 and a second opening 212. The first opening 210 of the solder resist layer 208 exposes part of the first trace 204. The second opening 212 of the solder resist layer 208 exposes part of the second trace 206. The part of the first trace 204 that is exposed is shown as a solid line while the part of the first trace 204 that is covered by the solder resist layer 208 is shown as a dashed line. Similarly, the part of the second trace 206 that is exposed is shown as a solid line while the part of the second trace 206 that is covered by the solder resist layer 208 is shown as a dashed line.

During the manufacturing process and/or assembly process of a packaging substrate, the packaging substrate may be subject to various forces which may cause one or more traces on the packaging substrate to peel off. Examples of manufacturing and/or assembly processes include roller process, picker process, handling process, bonding process (e.g., reflow bonding, thermal compression bonding) and post processing. During a thermal compression process, solder is applied to the openings (e.g., openings 210-212) in the solder resist layer 208 and the traces (e.g., traces 204-206) on the packaging substrate to connect a die to the packaging substrate. As the name implies, the solder resist layer 208 protects areas of the packaging substrate and/or traces from the solder, preventing the solder from wetting to portions of the traces. As mentioned above, during this thermal compression process, a lot of stress occurs (e.g., thermal stress). In some instances, the traces are large enough to handle these stresses. However, there has been a trend towards smaller and finer pitch traces. In such cases, these smaller and finer pitch traces are unable to handle the stress and often fail (e.g., peeling of trace).

FIG. 3 illustrates an example of how a trace can fail during a thermal compression process. FIG. 3 illustrates a first trace 300 and a second trace 302 on a packaging substrate. The first and second traces 300-302 are covered with a solder resist layer 304. The solder resist layer 304 has a first opening 306 that exposes part of the first trace 300. The solder resist layer 304 also has a second opening 308 that exposes part of the second trace 302. The top diagram of FIG. 3 illustrates how traces look before a thermal compression process is applied. The bottom diagram of FIG. 3 illustrates how traces may look after a thermal compression process is applied. As shown in FIG. 3, part of the first trace 300 and part of the second trace 302 have sheared off from their respective traces 300-302 and/or peeled off from a packaging substrate. This phenomenon is the result of using smaller and finer pitch traces, which have smaller areas to absorb the stress during a thermal compression bonding process. As a result of this failure, there is no connection that occurs through the traces 300-302.

It should be noted that the peeling off of the traces shown in FIG. 3 is not limited to the thermal compression bonding process. As mentioned above, the peeling of the traces from packaging substrates may occur at any stage of the manufacturing and/or assembly process of the packaging substrate. As such, FIG. 3 may also represent how a trace may look during a different stage of a manufacturing and/or assembly process of a packaging substrate.

Therefore, there is a need for an improved design to increase pad adhesion and ensure that traces do not break or shear off during an assembly/bonding process.

### SUMMARY

Various features, apparatus and methods described herein provide anchoring a trace on a substrate to reduce peeling of the trace.

A first example provides a semiconductor device that includes a packaging substrate, a trace coupled to the packaging substrate, and a solder resist layer covering a part of the trace. The trace includes a first portion having a first width, and a second portion having a second width that is wider than the first width.

According to one aspect, the solder resist layer further includes an opening such that the second portion of the trace is exposed. In some implementations, the trace further includes a third portion located between the first portion and second portion of the trace. The third portion of the trace is exposed through an opening in the solder resist layer. The second portion of the trace covered with the solder resist layer.

According to an aspect, the second portion of the trace and the first portion of the trace form a T-shape. In some implementations, the second portion of the trace and the first portion of the trace form an L-shape. In some implementations, the second portion of the trace has a rectangular shape. In some implementations, the second portion of the trace has a circular shape.

According to one aspect, the second portion of the trace has a trapezoid shape, the trapezoid shape comprising the second width and a third width. The third width is less than the second width. In some implementations, the semiconductor device further includes a second trace coupled to the packaging substrate. The second trace comprising the first width. The second trace includes a third portion and a fourth portion. The fourth portion has a trapezoid shape that includes the second width and the third width. The trace is aligned in a first direction and the second trace is aligned in a second direction. In some implementations, the first direction is an opposite direction of the second direction.

According to an aspect, the second portion comprising the second width increases the area of the trace coupled to the packaging substrate to reduce the likelihood of the trace peeling from the packaging substrate during a manufacturing process of the packaging substrate.

According to one aspect, the second portion comprising the second width increases the area of the trace coupled to the packaging substrate to reduce the likelihood of the trace peeling from the packaging substrate during an assembly process of the packaging substrate.

According to an aspect, the second portion comprising the second width increases the area of the trace coupled to the packaging substrate to reduce the likelihood of the trace peeling from the packaging substrate during a bonding process of a die to the packaging substrate.

According to one aspect, the semiconductor device further includes a die coupled to the packaging substrate.

According to one aspect, the semiconductor device is incorporated into at least one of a music player, a video player, an entertainment unit, a navigation device, a communications device, a mobile device, a mobile phone, a smartphone, a personal digital assistant, a fixed location terminal, a tablet computer, and/or a laptop computer.

A second example provides an apparatus that includes a packaging substrate, means for providing an electrical path on the packaging substrate, and means for covering a part of the means for providing the electrical path. The means for providing the electrical path includes a first portion having a first width, and a second portion having a second width that is wider than the first width.

According to one aspect, the means for covering further includes an opening such that the second portion of the means for providing the electrical path is exposed.

According to an aspect, the means for providing the electrical path farther includes a third portion located between the first portion and second portion. The third portion of the means for providing the electrical path is exposed through an opening in the means for covering. The second portion of the means for providing the electrical path is covered with the means for covering.

According to one aspect, the second portion and the first portion of the means for providing the electrical path form a T-shape. In some implementations, the second portion and the first portion of the means for providing the electrical path form an L-shape. In some implementations, the second portion of the means for providing the electrical path has a rectangular shape. In some implementations, the second portion of the means for providing the electrical path has a circular shape.

According to an aspect, the second portion of the means for providing the electrical path has a trapezoid shape. The trapezoid shape has the second width and a third width. The third width is less than the second width. In some implementations, the apparatus further includes a second means for providing the electrical path on the packaging substrate. The second means for providing the electrical path includes the first width. The second means for providing the electrical path includes a third portion and a fourth portion. The fourth portion has a trapezoid shape that includes the second width and the third width. The means for providing the electrical path is aligned in a first direction and the second means for providing the electrical path is aligned in a second direction. In some implementations, the first direction is an opposite direction of the second direction.

According to one aspect, the second portion comprising the second width increases the area of the means for providing the electrical path coupled to the packaging substrate to reduce the likelihood of the means for providing the electrical path peeling from the packaging substrate during a manufacturing process of the packaging substrate.

According to an aspect, the second portion comprising the second width increases the area of the means for providing the electrical path coupled to the packaging substrate to reduce the likelihood of the means for providing the electrical path peeling from the packaging substrate during an assembly process of the packaging substrate.

According to one aspect, the second portion comprising the second width increases the area of the means for providing the electrical path coupled to the packaging substrate to reduce the likelihood of the means for providing the electrical path peeling from the packaging substrate during a bonding process of a die to the packaging substrate.

According to an aspect, the apparatus further includes a die coupled to the packaging substrate.

According to one aspect, the apparatus is incorporated into at least one of a music player, a video player, an entertainment unit, a navigation device, a communications device, a mobile device, a mobile phone, a smartphone, a personal digital assistant, a fixed location terminal, a tablet computer, and/or a laptop computer.

A third example provides a method for manufacturing a packaging substrate. The method provides a packaging substrate. The method further provides a trace on the packaging substrate. The trace includes a first portion having a first width, and a second portion having a second width that is wider than the first width. The method provides a solder resist layer covering a part of the trace.

According to one aspect, the solder resist layer further comprises an opening such that the second portion of the trace is exposed. In some implementations, the trace further includes a third portion located between the first portion and second portion of the trace. The third portion of the trace is exposed through an opening in the solder resist layer. The second portion of the trace is covered with the solder resist layer.

According to an aspect, the second portion of the trace and the first portion of the trace form a T-shape. In some implementations, the second portion of the trace and the first portion of the trace form an L-shape. In some implementations, the second portion of the trace has a rectangular shape. In some implementations, the second portion of the trace has a circular shape.

According to one aspect, the second portion of the trace has a trapezoid Shape. The trapezoid shape comprises the second width and a third width. The third width being less than the second width. In some implementations, the method farther provides a second trace coupled to the packaging substrate. The second trace has the first width. The second trace includes a third portion and a fourth portion. The fourth portion has a trapezoid shape that includes the second width and the third width. The trace is aligned in a first direction and the second trace is aligned in a second direction. In some implementations, the first direction is an opposite direction of the second direction.

According to an aspect, the second portion comprising the second width increases the area of the trace coupled to the packaging substrate to reduce the likelihood of the trace peeling from the packaging substrate during a manufacturing process of the packaging substrate.

According to one aspect, the second portion comprising the second width increases the area of the trace coupled to the packaging substrate to reduce the likelihood of the trace peeling from the packaging substrate during an assembly process of the packaging substrate.

According to an aspect, the second portion comprising the second width increases the area of the trace coupled to the packaging substrate to reduce the likelihood of the trace peeling from the packaging substrate during a bonding process of a die to the packaging substrate.

### DRAWINGS

Various features, nature and advantages may become apparent from the detailed description set forth below when taken in conjunction with the drawings in which like reference characters identify correspondingly throughout.

FIG. 1 illustrates a thermal compression flip chip coupled to a packaging substrate.

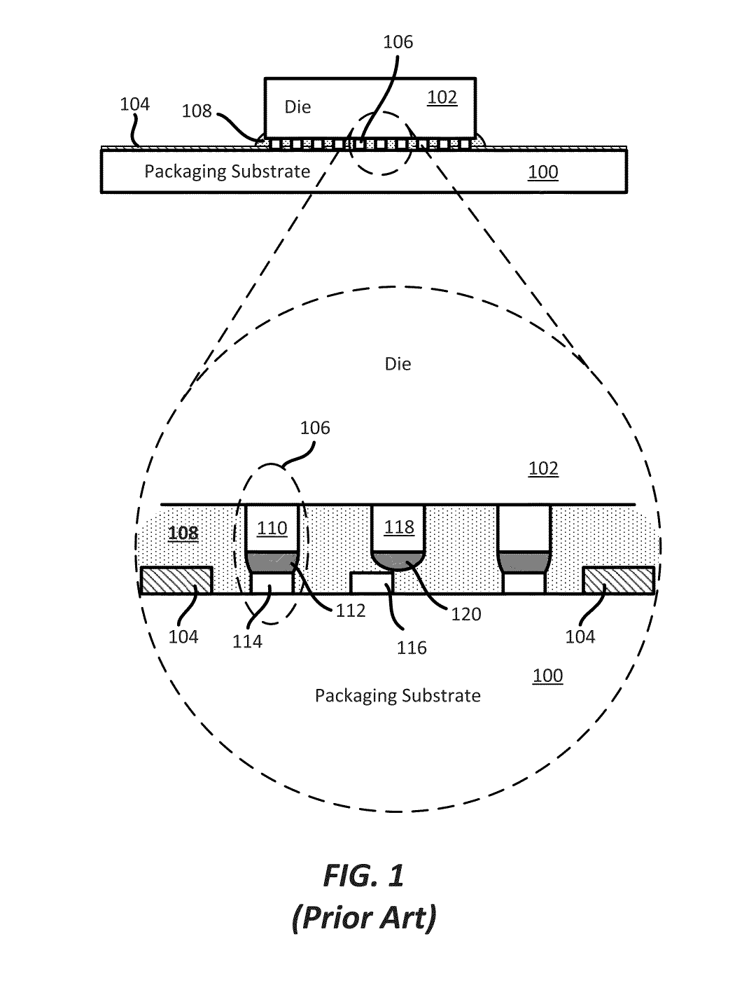

FIG. 2 illustrates a close up view of a packaging substrate that includes traces and a solder resist layer.

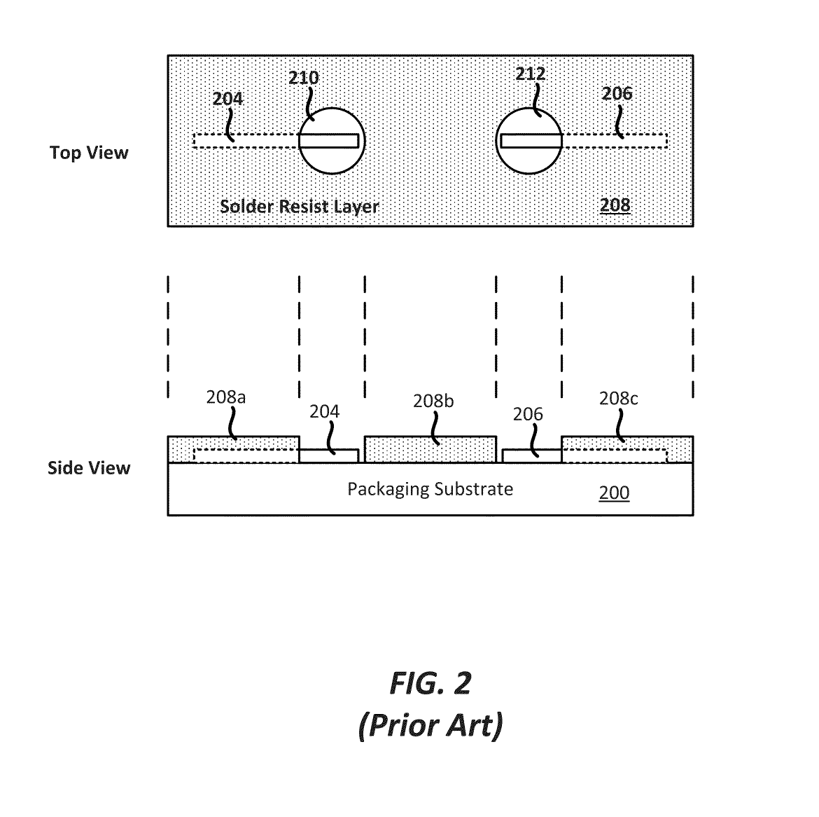

FIG. 3 illustrates how a trace on a packaging substrate may fail during a thermal compression bonding process.

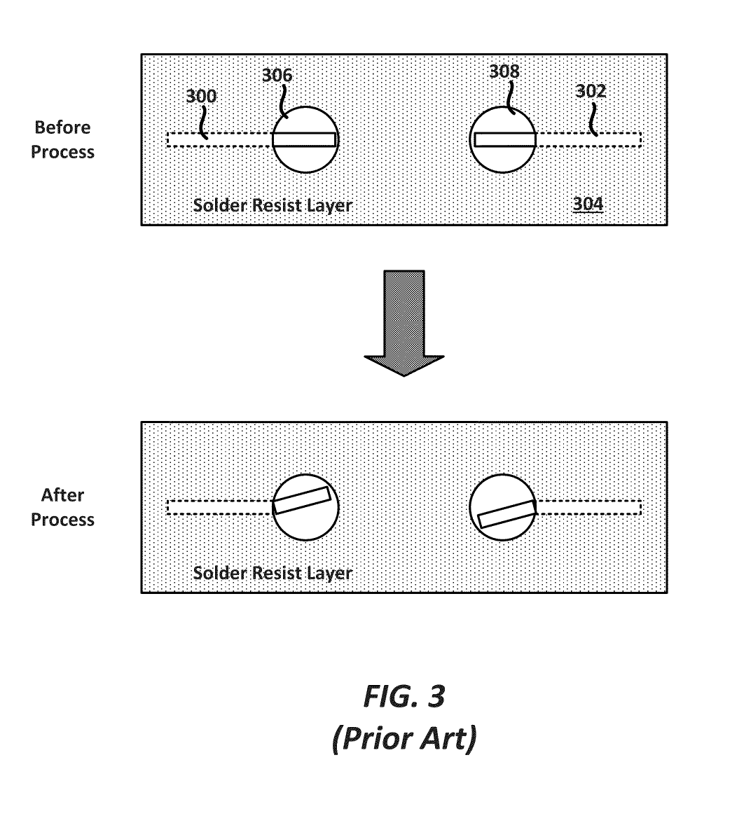

FIG. 4 illustrates a close up view of a packaging substrate that includes traces, anchoring pads, and a solder resist layer.

FIG. 5 illustrates a close up view of another packaging substrate that includes traces, anchoring pads, and a solder resist layer.

FIG. 6 illustrates a close up view of another packaging substrate that includes traces, anchoring pads, and a solder resist layer.

FIG. 7 illustrates a close up view of several packaging substrates that includes traces and different anchoring portions.

FIG. 8 illustrates a close up view of other several packaging substrates that includes traces and different anchoring portions.

FIG. 9 illustrates a flow diagram of a method for manufacturing a packaging substrate that includes traces and anchor portions.

FIG. 10 illustrates a sequence for manufacturing a packaging substrate that includes traces and anchor portions.

FIG. 11 illustrates various electronic devices that may integrate the IC described herein.

### DETAILED DESCRIPTION

In the following description, specific details are given to provide a thorough understanding of the various aspects of the disclosure, However, it will be understood by one of ordinary skill in the art that the aspects may be practiced without these specific details, For example, circuits may be shown in block diagrams in order to avoid obscuring the aspects in unnecessary detail. In other instances, well-known circuits, structures and techniques may not be shown in detail in order not to obscure the aspects of the disclosure.

### Overview

Some exemplary implementations of this disclosure pertain to a semiconductor device that includes a packaging substrate, a trace coupled to the packaging substrate, and a solder resist layer that covers part of the trace. The trace includes a first portion having a first width, and a second portion having a second width that is wider than the first width. In some implementations, the second portion having the second width increases the area of the trace coupled to the packaging substrate to reduce the likelihood of the trace peeling from the packaging substrate. In some implementations, the solder resist layer further includes an opening such that the second portion of the trace is exposed. In some implementations, the trace further includes a third portion located between the first portion and second portion of the trace and where the third portion of the trace is exposed through an opening in the solder resist layer. In some implementations, the second portion of the trace is covered with the solder resist layer.

### Exemplary Packaging Substrate Having Anchoring on Trace

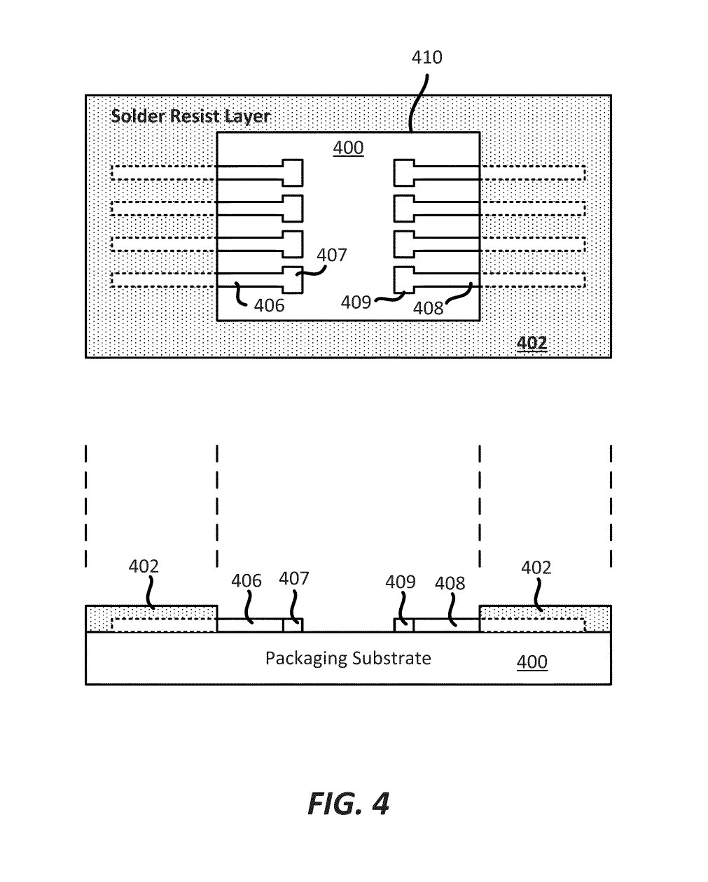

FIG. 4 illustrates a top view of a packaging substrate that includes anchoring on traces in some implementations. As shown in FIG. 4, a package substrate 400 includes a solder resist layer 402 and several traces (e.g., traces 406, 408). The traces are positioned on top of a packaging substrate 400. A trace provides an electrical path on the packaging substrate. In some implementations, a die may be coupled to one or more traces on the packaging substrate. Thus, in some implementations, one or more traces may provide an electrical path to/from the die that is coupled to the packaging substrate. Different implementations may have traces with different pitches and/or spacing. In some implementations, the pitch between traces is 100 microns (μm) or less. In some implementations, a pitch defines a center to center distance between two neighboring traces. In some implementations, the spacing between traces is between 10-20 microns (μm). In some implementations, a spacing defines a distance between edges of two neighboring traces.

The solder resist layer 402 is positioned on top of the packaging substrate 400 and over a portion of the traces. The solder resist layer 402 includes an opening 410. The opening 410 in the solder resist layer 402 exposes parts/portions of the traces (e.g., traces 406, 408) and part of the packaging substrate 400. Thus, any part of a trace or a packaging substrate that is in the opening 410 is free of any solder resist in some implementations. For example, as shown in FIG. 4, a first portion of trace (e.g., trace 406) is covered with the solder resist layer 402, while a second portion of the trace (e.g., anchor 407) and a third portion (e.g., middle portion) of the trace (e.g., trace 106) are free of the solder resist layer 402. During a bonding process (e.g., thermal compression bonding, reflow bonding) that couples (e.g., assembles) a die to a packaging substrate, an electronic connection (which includes an UBM structure and solder) of a die is coupled to some or all of the exposed parts (e.g., free of solder resist) of the traces (e.g., traces 406, 408) of the packaging substrate 400.

FIG. 4 also illustrates anchor portions (e.g., anchor portions 407, 409). As shown in FIG. 4, each trace may include several portions, including a first portion and an anchor portion (e.g., second portion). Thus, for example, trace 406 includes a first portion and an anchor portion 407 (e.g., second portion of trace 407). Similarly, trace 408 includes a first portion and an anchor portion 409. In some implementations, the anchor portion (e.g., second portion) of the trace is located at the end of the portion of the trace that is exposed (e.g., the end portion of the trace that is not covered with solder resist/free of solder resist). In some implementations, these anchor portions (e.g., anchor portions 407, 409) may be referred to as end portions and/or second portions of a trace. In some implementations, the anchor portion (e.g., second portion) may be part of the trace or it may be coupled to the trace. In some implementations, the traces have a first width, and the anchor portions have a second width that is greater than the first width of the traces. For example, a first portion of the trace has a first width, and a second portion of the trace (e.g., end portion or anchor portion) has a second width that is greater than the first width of the first portion of the trace. As shown in FIG. 4, the anchor portion has the shape of a rectangle. Moreover, FIG. 4 shows that each anchor portion forms a T-shape with its respective trace. In some implementations, these anchor portions (e.g., anchor portion 407, 409) are portions of the trace that a solder and a UBM structure of a die are coupled to during a bonding process (e.g., thermal compression bonding process).

In some implementations, the anchor portion (e.g., second portion of the trace) increases the surface area of the trace, effectively increasing the area of the trace that is connected to the packaging substrate. This increase in the surface area coupled to the packaging substrate allows the trace to absorb more stress (e.g., more force), as stress will be spread out over a larger area of the trace which includes the anchor portion. As a result, the traces are less likely to break, shear and/or peel off from the packaging substrate during a manufacturing process and/or assembly process of the packaging substrate (e.g., during a thermal compression bonding process). As such, adding an anchor portion (e.g., second portion) to the trace increases the likelihood of good electrical connections between a die and a packaging substrate. Examples of manufacturing and/or assembly processes include roller process, picker process, handling process, bonding process (e.g., reflow bonding, thermal compression bonding) and post processing. As described above, force and/or stress that can cause traces to break, shear and/or peel off may be applied to the traces during any stage of the manufacturing and/or assembly process. The term “peel off” as used herein may include shearing and breaking.

As shown in FIG. 4, the anchor portions (e.g., anchor portion 407, 409) have a rectangular shape that each has a width that is larger than the width of the traces (e.g., traces 406, 408). However, different implementations may use different configurations of anchor portions. For instances, the anchor portions (e.g., second portions of traces) may have different shapes, such as a circle, square and/or triangle.

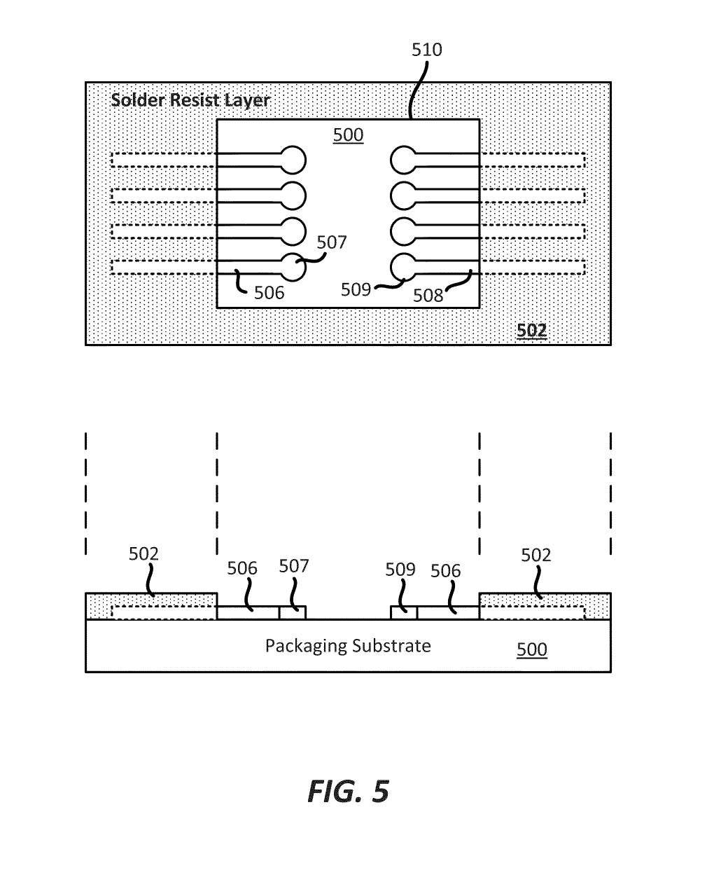

FIG. 5 illustrates a packaging substrate that includes traces having anchor portions with a different shape. Specifically, FIG. 5 illustrates a packaging substrate 500 that includes traces having anchor portions (e.g., second portions) with circular shapes. As shown in FIG. 5, the traces (e.g., traces 506, 508) include anchor portions (e.g., anchor portions 507, 509) that have circular shapes. In some implementations, these anchor portions (e.g., anchor portions 507, 509) may be referred to as end portions and/or second portions of a trace. In some implementations, the anchor portion may be part of the trace or it may be coupled to the trace. In some implementations, each anchor portion has a diameter that is larger than the width of its respective trace. For example, in some implementations, a second portion has a diameter that is larger than the width of a first portion of a trace.

FIG. 5 also illustrates a solder resist layer 502 on top of the packaging substrate 500 and the traces (e.g., traces 506, 508). The solder resist layer includes an opening 510. The opening 510 of the solder resist layer 502 is positioned above the anchor portions (e.g., anchor portions 507, 509) and thus each anchor portion (e.g., second portion of trace) is exposed and not covered by any solder resist (e.g., each anchor portion is free of any solder resist). In addition, FIG. 5 also illustrates that some portions of the traces (e.g., traces 506, 508) which are located in the opening 510 are also exposed and free of any solder resist. For example, as shown in FIG. 5, a first portion of trace (e.g., trace 506) is covered with the solder resist layer 502, while a second portion of the trace (e.g., anchor 507) and a third portion of the trace (e.g., trace 506) are free of the solder resist layer 502.

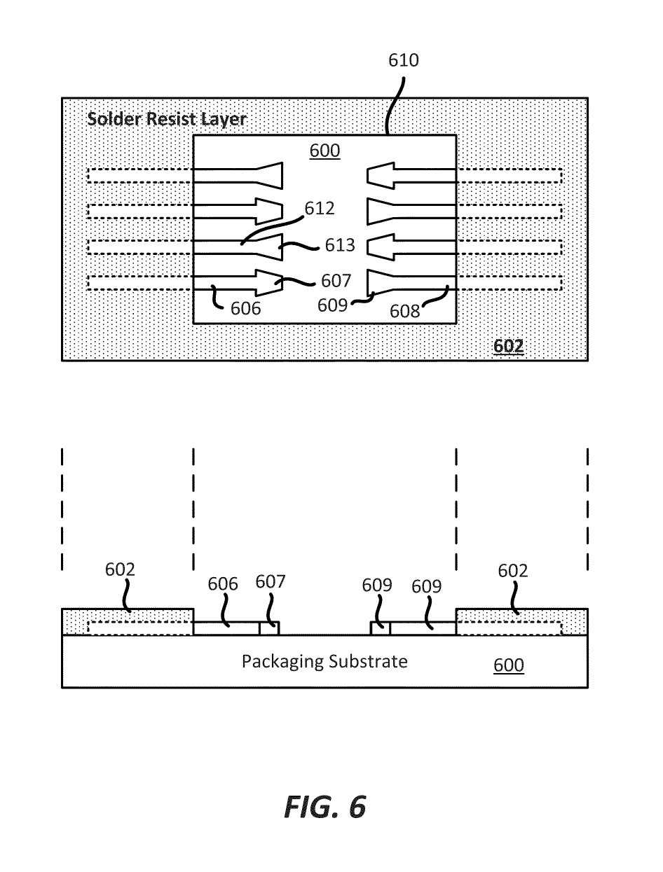

FIG. 6 illustrates a packaging substrate that includes traces having anchor portions with a different shape. Specifically, FIG. 6 illustrates a packaging substrate 600 that includes traces having anchor portions (e.g., second portions) with trapezoid shapes. As shown in FIG. 6, the traces (e.g., traces 606, 608, 612) include anchor portions (e.g., anchor portions 607, 609, 613) that have a trapezoid shape. In some implementations, these anchor portions (e.g., anchor portions 607, 609, 613) may be referred to as end portions and/or second portions of a trace. In some implementations, the anchor portion may be part of the trace or it may be coupled to the trace. In some implementations, each anchor portion (e.g., second portion) has a second width and a third width, where the second third is larger/wider than the second width and the first width of its respective trace (e.g., first portion of trace). As further shown in FIG. 6, the anchor portions may be aligned in different directions (e.g., first direction, second direction). That is, some anchor portions (e.g., second portions) may be aligned in a first direction so that the wider portion of the anchor portion (e.g., second portion) is coupled to the trace, while some anchor portions may be aligned in a second direction (e.g., where the second direction is opposite of the first direction) so that the narrower portion of the anchor portion is coupled to the trace. In some implementations, the alignment and coupling of the anchor portion may alternate back and forth (where the narrower or wider portion of the trapezoid shape anchor portion is coupled to the trace) between neighboring traces/anchor portions. One benefit of this alternating approach, as shown in FIG. 6, is that it helps preserves as much spacing as possible between anchor portions (e.g., second portions), thereby reducing the likelihood of crosstalk between the neighboring anchor portions (e.g., second portions) of traces.

FIG. 6 also illustrates a solder resist layer 602 on top of the packaging substrate 600 and the traces (e.g., traces 606, 608). The solder resist layer 602 includes an opening 610. The opening 610 of the solder resist layer 602 is positioned above the anchor portions (e.g., anchor portions 607, 609, 613) and thus each anchor portion is exposed and not covered by any solder resist (e.g., each anchor portion free of any solder resist). In addition, FIG. 6 also illustrates that some portions of the traces (e.g., traces 606, 608, 613) which are located in the opening 610 are also exposed and free of any solder resist. For example, as shown in FIG. 6, a first portion of trace (e.g., trace 606) is covered with the solder resist layer 602, while a second portion of the trace (e.g., anchor 607) and a third portion of the trace (e.g., trace 606) are free of the solder resist layer 602.

FIGS. 4-6 illustrate one large continuous opening (e.g., openings 410, 510, 610) in a solder resist layer to expose several portions of traces and/or anchor portions (e.g., second portions). However, in some implementations, several openings in the solder resist layer may be used to expose portions of traces and anchor portions (e.g., second portions of traces). In some implementations, each opening may be large enough to expose portions of one trace and/or anchor portion of a trace, instead of multiple traces and anchor portions. Thus, in some implementations, an opening in the solder resist layer may be defined/provided for each trace and/or anchor portion of a trace. One advantage of such an approach is that there is less likely to be bridging of neighboring traces and/or anchor portions, when an opening is defined/provided for each trace and/or anchor portion of a trace. In some implementations, different portions of the trace is exposed and/or covered by a solder resist layer.

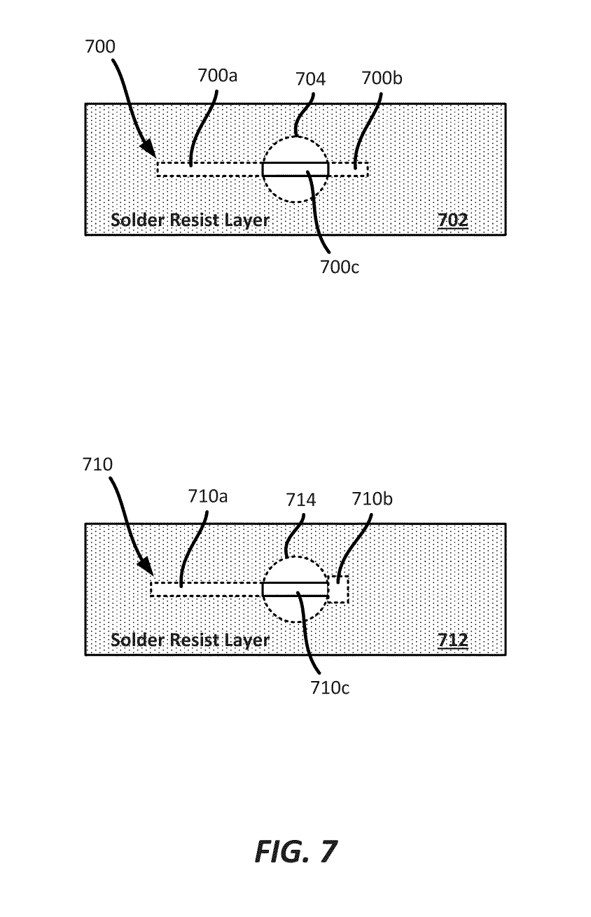

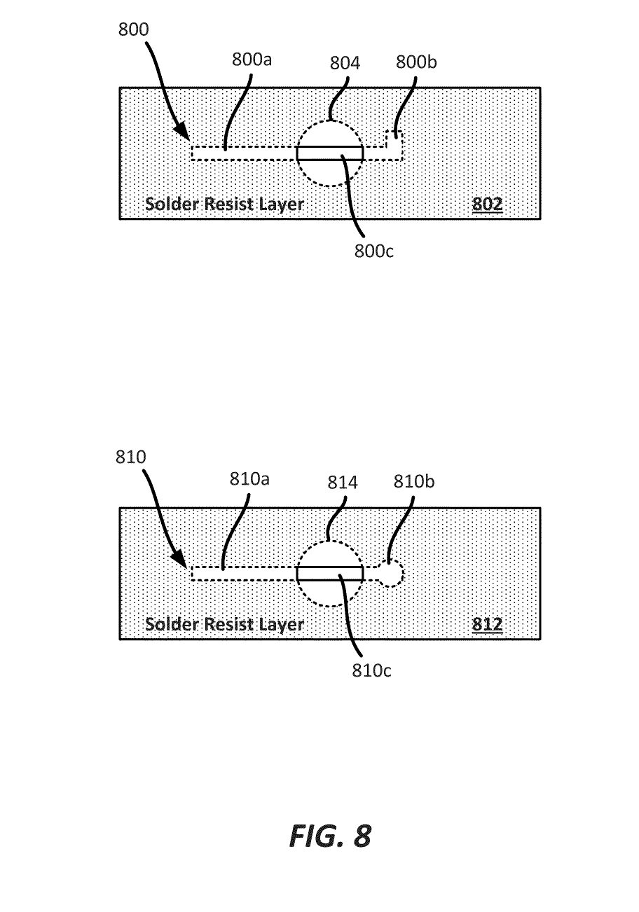

FIGS. 7-8 illustrate examples of different implementations of anchor portions and openings in the solder, resist layer.

The top diagram of FIG. 7 illustrates a portion of a packaging substrate that includes a trace 700 and a solder resist layer 702. The solder resist layer 702 includes an opening 704. As shown in FIG. 7, the trace 700 includes a first trace portion 700a, a second trace portion 700b and a third trace portion 700c. The first, second, and third trace portions 700a-700c have a first width, The first trace portion 700a and the second trace portion 700b are covered by the solder resist layer 702. In some implementations, the second trace portion 700b may be an end portion (e.g., anchor portion). The third trace portion 700c is a middle trace portion of the trace 700 in some implementations. As shown in FIG. 7, the third trace portion 700c is exposed (e.g., the trace portion is not covered by a solder resist layer/free of solder resist), as shown by the opening 704 of the solder resist layer 702 being positioned above the middle trace portion 700c. In some implementations, the second trace portion 700b and the solder resist layer 702 anchor the trace 700 so as help prevent the trace 700 from peeling off during an manufacturing and/or assembly process (e.g., thermal compression bonding process). In some implementations, the middle trace portion 700c is the portion of the trace that a die is coupled to during a bonding process that couples the die to the packaging substrate.

The bottom diagram of FIG. 7 illustrates another portion of a packaging substrate that includes a trace 710 and a solder resist layer 712. The solder resist layer 712 includes an opening 714. As shown in FIG. 7, the trace 712 includes a first trace portion 710a, a second trace portion 710b and a third trace portion 710c. The first and third trace portions 710a and 710c have a first width. The second trace portion 710b includes a rectangular shape end portion and forms a T-shape with the third trace portion 710c. The second trace portion 710 has a second width that is greater/wider than the first width of the third trace portion 710c and/or the first trace portion 710a. As shown in FIG. 7, the third trace portion 710c is exposed (e.g., the trace portion is not covered by a solder resist layer/free of solder resist), as shown by the opening 714 of the solder resist layer 712 being positioned above the third trace portion 710c. As further shown in FIG. 7, the first and second trace portions 710a and 710b are covered by the solder resist layer 712. The third trace portion 710c is a middle trace portion of the trace 710 in some implementations. In some implementations, the middle trace portion 710c is the portion of the trace that a die is coupled to during a bonding process that couples the die to the packaging substrate.

FIG. 8 illustrates other examples of different implementations of anchor portions and openings in the solder resist layer. Specifically, the top diagram of FIG. 8 illustrates another portion of a packaging substrate that includes a trace 800 and a solder resist layer 802. The solder resist layer 802 includes an opening 804. As shown in FIG. 8, the trace 802 includes a first trace portion 800a, a second trace portion 800b and a third trace portion 800c The first and third trace portions 800a and 800c have a first width. The second trace portion 800b includes a rectangular shape end portion and forms an L-shape with the third trace portion 800c. The second trace portion 800b has a second width that is greater/wider than the first width of the third trace portion 800c and/or the first trace portion 800a. As shown in FIG. 8, the third trace portion 800c is exposed (e.g., the trace portion is not covered by a solder resist layer/free of solder resist), as shown by the opening 804 of the solder resist layer 802 being positioned above the third trace portion 800c. As further shown in FIG. 8, the first and second trace portions 800a and 800b are covered by the solder resist layer 802. The third trace portion 800c is a middle trace portion of the trace 800 in some implementations. In some implementations, the middle trace portion 800c is the portion of the trace that a die is coupled to during a bonding process that couples the die to the packaging substrate.

The bottom diagram of FIG. 8 illustrates another portion of a packaging substrate that includes a trace 810 and a solder resist layer 812. The solder resist layer 812 includes an opening 814. As shown in FIG. 8, the trace 810 includes a first trace portion 810a, a second. trace portion 810b and a third trace portion 810c. The first and third trace portions 810a and 810c have a first width. The second trace portion 810b includes a circular shape end portion. The second trace portion 810b has a second diameter/second width that is greater/wider than the first width of the third trace portion 810c and/or the first trace portion 810a. As shown in FIG. 8, the third trace portion 810c is exposed (e.g., the trace portion is not covered by a solder resist layer/free of solder resist), as shown by the opening 814 of the solder resist layer 812 being positioned above the third trace portion 810c. As further shown in FIG. 8, the first and second trace portions 810a and 810b are covered by the solder resist layer 812. The third trace portion 810c is a middle trace portion of the trace 810 in some implementations. In some implementations, the middle trace portion 810c is the portion of the trace that a die is coupled to during a bonding process that couples the die to the packaging substrate.

The various examples illustrated in FIGS. 7-8 reduce the likelihood of the traces from shearing, peeling and/or breaking from a packaging substrate by increasing the size of the surface area of the trace that is coupled to the packaging substrate and by using the solder resist layer to help absorb some of the stress during a manufacturing and/or assembly process (e.g., during a bonding process that couples a die to a packaging substrate).

Having described a packaging substrate that includes traces with anchor portions a method for manufacturing such a packaging substrate will now be described. below.

Exemplary Method for Manufacturing a Packaging Substrate that Includes Traces with an Anchor Portion

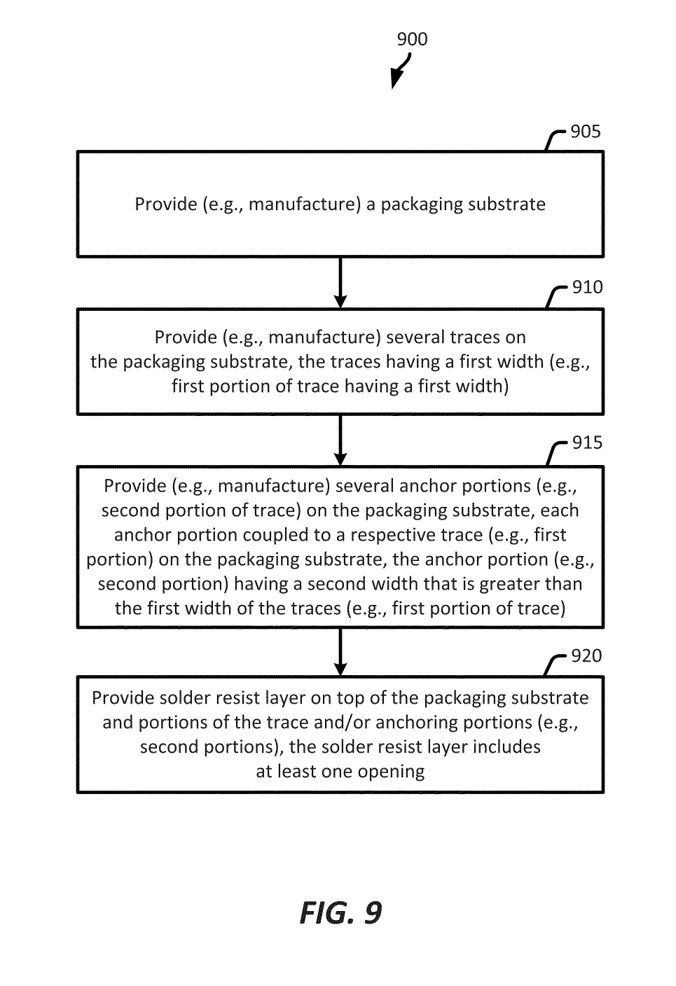

FIG. 9 illustrates a flow diagram of a method for manufacturing a packaging a substrate that includes traces with an anchor portion.

The method provides (at 905) a packaging substrate. In some implementations, providing a packaging substrate includes manufacturing a packaging substrate. The method provides (at 910) several traces on the packaging substrate. In some implementations, providing several traces includes defining/manufacturing several traces on the packaging substrate. Different implementations may use different traces. In some implementations, the traces are copper traces. The traces provided on the packaging substrate may have a first width. For example, a first portion of a trace may have a first width. In some implementations, a trace may have a third portion that also has a first width.

The method provides (at 915) several anchor portions (e.g., second portion of a trace) on the packaging substrate. In some implementations, an anchor portion is provided to a respective trace on the packaging substrate. More specifically, the anchor portion may be provided to an end portion of a respective trace on the packaging substrate. The anchor portions may have a second width or diameter. The second width or diameter of the anchor portion may be greater/wider than the first width of the traces (e.g., first width of the first portion and/or third portion of a trace). The anchor portions may have different shapes (e.g., circle, rectangle, square, oval, trapezoid). In some implementations, the anchor portions are provided to the packaging substrate such that the anchor portion and the trace form a T-shaped trace or an L-shaped trace. For example, a second portion of the trace and the first portion of the trace may form a T-shaped trace or an L-shaped trace. In addition, in some implementations, a second portion of the trace and the third portion of the trace may form a T-shaped trace or an L-shaped trace. In some implementations, providing the anchor portions (e.g., second portion) includes defining/manufacturing anchor portions on the packaging substrate. The anchor portions may be made of the same material as the traces on the packaging substrate. For example, the anchor portions may be made of copper in some implementations. Although FIG. 9 illustrates that the anchor portions are provided after the traces, in some implementations, the anchor portions (e.g., second portion) and the traces (e.g., first portion and/or third portion) are concurrently provided to the packaging substrate. That is, in some implementations, the trace and anchor portion of the trace is provided/defined/manufactured on the packaging substrate during the same process. Moreover, the trace, the anchor portion of the trace, and the packaging substrate may be provided/defined/manufactured during the same process (e.g., concurrently provided during the same manufacturing process). Further, in some implementations, the trace and anchor may be manufactured as a single structure. In other implementations, the trace and anchor may be two separate structures coupled together.

Once the packaging substrate, the traces and the anchor portions are provided, the method provides (at 920) a solder resist layer on top of the substrate, trace and/or anchor portions of the traces. Different implementations may provide the solder resist layer differently. In sonic implementations, providing a solder resist layer includes providing a solder resist layer that includes one continuous opening. The opening may expose several portions of traces (e.g., first portion and/or third portion) and several anchor portions (e.g., second portion) in some implementations. Examples of one continuous opening in a solder resist layer that exposes several portions of traces and several anchor portions are shown in FIGS. 4-6. In some implementations, providing a solder resist layer includes providing a solder resist layer with multiple openings. In some implementations, an opening in the solder resist layer is provided for each portion of a trace and/or anchor portion. For example, the opening may be provided such that a middle portion (e.g., third portion) of a trace is exposed (e.g., free of solder resist), while the end portions of the trace including the anchor portion (e.g., second portion) of the trace is covered with a solder resist layer.

Having described a method for manufacturing a packaging substrate that includes traces having anchor portions, a sequence of how to manufacture a packaging substrate that includes traces having anchor portions will now be described.

Exemplary Sequence for Manufacturing a Packaging Substrate that Includes Traces with an Anchor Portion

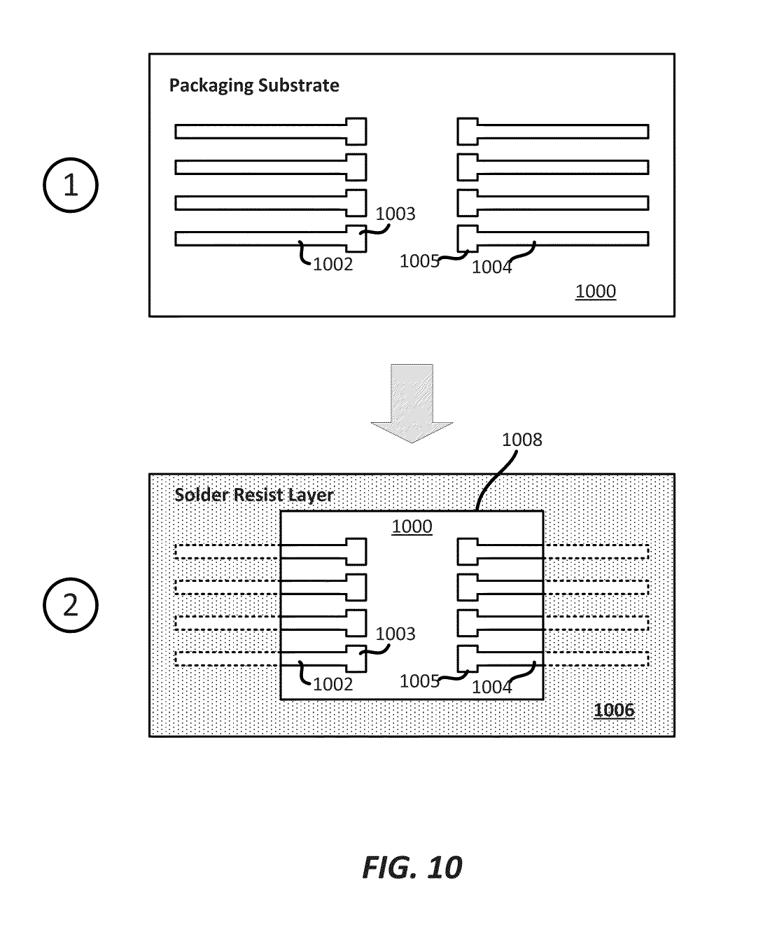

FIG. 10 illustrates a simplified sequence of manufacturing a packaging substrate that includes traces with an anchor portion. It should be noted that for the purpose of clarity and simplification, the process of FIG. 10 does not necessarily include all the steps and/or stages of manufacturing a packaging substrate. Moreover, in some instances, several steps and/or stages may have been combined into a single step and/or stage in order to simplify the description of the processes. In addition, the components illustrates in the FIG. 10 are merely conceptual illustrations and unless otherwise explicitly stated, do not necessarily represent the actual and/or relative dimensions of these components. In some instances, some of the dimensions may have been exaggerated to clearly illustrate/distinguish features of some of the components.

FIG. 10 illustrates a simplified sequence for manufacturing a packaging a substrate that includes traces with an anchor portion.

At stage 1, a packaging substrate 1000 is provided. As further shown in stage 1, the packaging substrate 1000 includes several traces (e.g., traces 1002, 1004) and several anchor portions (e.g., anchor portions 1003, 1004). Different implementations may use different traces (e.g., first portion) and/or anchor portions (e.g., second portion). The traces and the anchor portions may be provided at the same time as the packaging substrate in some implementations (e.g., may be provided as a single structure at the same time). In some instances, the trace (e.g., first portion and/or third portion) and anchor portions (e.g., second portion) are provided after a packaging substrate is provided (e.g., defined). In some implementations, the traces and anchor portions are copper traces. The traces may have a first width. For example, a first portion and/or a third portion of a trace may have a first width. The anchor portion may be provided to an end portion of a respective trace on the packaging substrate. The anchor portions (e.g., second portion) may have a second width or diameter. The second width or diameter of the anchor portion may be greater/wider than the first width of the traces (e.g., first and/or third portions of the trace). The anchor portions (e.g., second portion) may have different shapes (e.g., circle, rectangle, square, oval, trapezoid). In some implementations, the anchor portions are provided to the packaging substrate such that the anchor portion and the trace form a T-shaped trace or an L-shaped trace.

At stage 2, a solder resist layer 1006 is provided on top of the packaging substrate 1000, portions of the traces and/or anchor portions of the traces. The solder resist layer 1006 includes a continuous opening 1008. The opening 1008 is positioned above portions of the traces and anchor portions. Different implementations may provide the solder resist layer 1006 differently. In some implementations, the opening 1008 is an area of the packaging substrate 1000 that a die is coupled to during a bonding process (e.g., thermal compression bonding process).

### Exemplary Electronic Devices

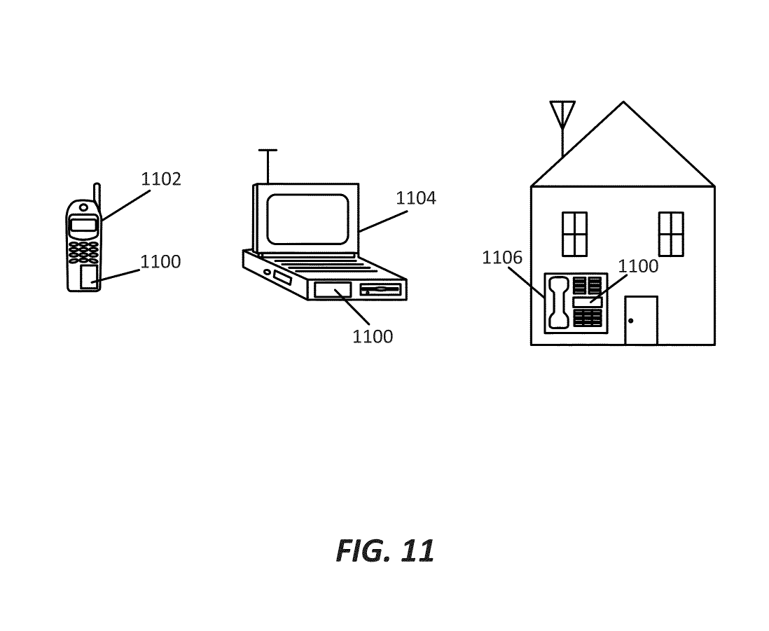

FIG. 11 illustrates various electronic devices that may be integrated with any of the aforementioned integrated circuit, die or package. For example, a mobile telephone 1102, a laptop computer 1104, and a fixed location terminal 1106 may include an integrated circuit (IC) 1100 as described herein. The IC 1100 may be, for example, any of the integrated circuits, dice or packages described herein. The devices 1102, 1104, 1106 illustrated in FIG. 11 are merely exemplary. Other electronic devices may also feature the IC 1100 including, but not limited to, mobile devices, hand-held personal communication systems (PCS) units, portable data units such as personal digital assistants, GPS enabled devices, navigation devices, set top boxes, music players, video players, entertainment units, fixed location data units such as meter reading equipment, communications devices, smartphones, tablet computers or any other device that stores or retrieves data or computer instructions, or any combination thereof.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling between two objects. For example, if object A physically touches object B, and object B touches object C, then objects A and C may still be considered coupled to one another even if they do not directly physically touch each other. For instance, the substrate of the die may he coupled to the packaging substrate even though the substrate of the die is never directly physically in contact with the packaging substrate.

The terms wafer and substrate may be used herein to include any structure having an exposed surface with which to form an integrated circuit (IC) according to aspects of the present disclosure. The term die may be used herein to include an IC. The term substrate is understood to include semiconductor wafers. The term substrate is also used to refer to semiconductor structures during fabrication, and may include other layers that have been fabricated thereupon. The term substrate includes doped and undoped semiconductors, epitaxial semiconductor layers supported by a base semiconductor, or semiconductor layers supported by an insulator, as well as other semiconductor structures well known to one skilled in the art. The term insulator is defined to include any material that is less electrically conductive than materials generally referred to as conductors by those skilled in the art. The term “horizontal” is defined as a plane substantially parallel to the conventional plane or surface of a wafer or substrate, regardless of the orientation of the wafer or substrate. The term “vertical” refers to a direction substantially perpendicular to the horizontal as defined above. Prepositions, such as “on,” “upper,” “side,” “higher,” “lower,” “over,” and “under” when used with respect to the integrated circuits described, herein are defined with respect to the conventional plane or surface being on the top surface of the wafer or substrate, regardless of the orientation of the wafer or substrate. The prepositions “on,” “upper,” “side,” “higher,” “lower,” “over,” and “under” are thereby defined with respect to “horizontal” and “vertical.”

One or more of the components, steps, features, and/or functions illustrated in FIGS. 4, 5, 6, 7, 8, 9, 10 and/or 11 may be rearranged and/or combined into a single component, step, feature or function or embodied in several components, steps, or functions. Additional elements, components, steps, and/or functions may also be added without departing front the invention.

Also, it is noted that the aspects of the present disclosure may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

The various features of the invention described herein can be implemented in different systems without departing from the invention. It should be noted that the foregoing aspects of the disclosure are merely examples and are not to be construed as limiting the invention. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

What is claimed is:

1. A semiconductor device comprising:
a packaging substrate;
a trace coupled to the packaging substrate, the trace comprising a first portion having a first width, and a second portion having a second width that is wider than the first width; and
a solder resist layer covering a part of the trace.

2. The semiconductor device of claim 1, wherein the solder resist layer further comprises an opening such that the second portion of the trace is exposed.

3. The semiconductor device of claim 1, wherein the trace further comprises a third portion located between the first portion and second portion of the trace and wherein the third portion of the trace is exposed through an opening in the solder resist layer, the second portion of the trace covered with the solder resist layer.

4. The semiconductor device of claim 1, wherein the second portion of the trace and the first portion of the trace form a T-shape.

5. The semiconductor device of claim 1, wherein the second portion of the trace and the first portion of the trace form an L-shape.

6. The semiconductor device of claim 1, wherein the second portion of the trace has a rectangular shape.

7. The semiconductor device of claim 1, wherein the second portion of the trace has a circular shape.

8. The semiconductor device of claim 1, wherein the second portion of the trace has a trapezoid shape, the trapezoid shape comprising the second width and a third width, the third width being less than the second width.

9. The semiconductor device of claim 8 further comprising a second trace coupled to the packaging substrate, the second trace comprising the first width, the second trace comprising a third portion and a fourth portion, the fourth portion comprising a trapezoid shape that includes the second width and the third width, wherein the trace is aligned in a first direction and the second trace is aligned in a second direction.

10. The semiconductor device of claim 9, wherein the first direction is an opposite direction of the second direction.

11. The semiconductor device of claim 1, wherein the second portion comprising the second width increases the area of the trace coupled to the packaging substrate to reduce the likelihood of the trace peeling from the packaging substrate during a manufacturing process of the packaging substrate.

12. The semiconductor device of claim 1, wherein the second portion comprising the second width increases the area of the trace coupled to the packaging substrate to reduce the likelihood of the trace peeling from the packaging substrate during an assembly process of the packaging substrate.

13. The semiconductor device of claim 1, wherein the second portion comprising the second width increases the area of the trace coupled to the packaging substrate to reduce the likelihood of the trace peeling from the packaging substrate during a bonding process of a die to the packaging substrate.

14. The semiconductor device of claim 1 further comprising a die coupled to the packaging substrate.

15. The semiconductor device of claim 1, wherein the semiconductor device is incorporated into at least one of a music player, a video player, an entertainment unit, a navigation device, a communications device, a mobile device, a mobile phone, a smartphone, a personal digital assistant, a fixed location terminal, a tablet computer, and/or a laptop computer.

16. An apparatus comprising:
a packaging substrate;
means for providing an electrical path on the packaging substrate, the means comprising a first portion having a first width, and a second portion having a second width that is wider than the first width; and
means for covering a part of the means for providing the electrical path.

17. The apparatus of claim 16, wherein the means for covering further comprises an opening such that the second portion of the means for providing the electrical path is exposed.

18. The apparatus of claim 16, wherein the means for providing the electrical path further comprises a third portion located between the first portion and second portion and wherein the third portion of the means for providing the electrical path is exposed through an opening in the means for covering, the second portion of the means for providing the electrical path covered with the means for covering.

19. The apparatus of claim 16, wherein the second portion and the first portion of the means for providing the electrical path form a T-shape.

20. The apparatus of claim 16, wherein the second portion and the first portion of the means for providing the electrical path form an L-shape.

21. The apparatus of claim 16, wherein the second portion of the means for providing the electrical path has a rectangular shape.

22. The apparatus of claim 16, wherein the second portion of the means for providing the electrical path has a circular shape.

23. The apparatus of claim 16, wherein the second portion of the means for providing the electrical path has a trapezoid shape, the trapezoid shape comprising the second width and a third width, the third width being less than the second width.

24. The apparatus of claim 23 further comprising a second means for providing the electrical path on the packaging substrate, the second means for providing the electrical path comprising the first width, the second means for providing the electrical path comprising a third portion and a fourth portion, the fourth portion comprising a trapezoid shape that includes the second width and the third width, wherein the means for providing the electrical path is aligned in a first direction and the second means for providing the electrical path is aligned in a second direction.

25. The apparatus of claim 24, wherein e first direction is an opposite direction of the second direction.

26. The apparatus of claim 16, wherein the second portion comprising the second width increases the area of the means for providing the electrical path coupled to the packaging substrate to reduce the likelihood of the means for providing the electrical path peeling from the packaging substrate during a manufacturing process of the packaging substrate.

27. The apparatus of claim 16, wherein the second portion comprising the second width increases the area of the means for providing the electrical path coupled to the packaging substrate to reduce the likelihood of the means for providing the electrical path peeling from the packaging substrate during an assembly process of the packaging substrate.

28. The apparatus of claim 16, wherein the second portion comprising the second width increases the area of the means for providing the electrical path coupled to the packaging substrate to reduce the likelihood of the means for providing the electrical path peeling from the packaging substrate during a bonding process of a die to the packaging substrate.

29. The apparatus of claim 16 further comprising a die coupled to the packaging substrate.

30. The apparatus of claim 16, wherein the apparatus is incorporated into at least one of a music player, a video player, an entertainment unit, a navigation device, a communications device, a mobile device, a mobile phone, a smartphone, a personal digital assistant, a fixed location terminal, a tablet computer, and/or a laptop computer.

31. A method for manufacturing a packaging substrate, comprising:
providing a packaging substrate;
providing a trace on the packaging substrate, the trace comprising a first portion having a first width, and a second portion having a second width that is wider than the first width; and
providing a solder resist layer covering a part of the trace.

32. The method of claim 31, wherein the solder resist layer further comprises an opening such that the second portion of the trace is exposed.

33. The method of claim 31, wherein the trace further comprises a third portion located between the first portion and second portion of the trace and wherein the third portion of the trace is exposed through an opening in the solder resist layer, the second portion of the trace covered with the solder resist layer.

34. The method. of claim 31, wherein the second portion of the trace and the first portion of the trace form a T-shape.

35. The method of claim 31, wherein the second portion of the trace and the first portion of the trace form an L-shape.

36. The method of claim 31, wherein the second portion of the trace has a rectangular shape.

37. The method of claim 31, wherein the second portion of the trace has a circular shape.

38. The method of claim 31, wherein the second portion of the trace has a trapezoid shape, the trapezoid shape comprising the second width and a third width, the third width being less than the second width.

39. The method of claim 38 further comprising providing a second trace on the packaging substrate, the second trace comprising the first width, the second trace comprising a third portion and a fourth portion, the fourth portion comprising a trapezoid shape that includes the second width and the third width, wherein the trace is aligned in a first direction and the second trace is aligned in a second direction.

40. The method of claim 39, wherein the first direction is an opposite direction of the second direction.

41. The method of claim 31, wherein the second portion comprising the second width increases the area of the trace coupled to the packaging substrate to reduce the likelihood of the trace peeling from the packaging substrate during a manufacturing process of the packaging substrate.

42. The method of claim 31, wherein the second portion comprising the second width increases the area of the trace coupled to the packaging substrate to reduce the likelihood of the trace peeling from the packaging substrate during an assembly process of the packaging substrate.

43. The method of claim 31, wherein the second portion comprising the second width increases the area of the trace coupled to the packaging substrate to reduce the likelihood of the trace peeling from the packaging substrate during a bonding process of a die to the packaging substrate.

44. The method of claim 31 further comprising coupling a die to the packaging substrate.
